(19) United States
(12) Patent Application Publication
(10) Pub. No.: US 2010/0134979 A1
(43) Pub. Date: Jun. 3, 2010

(54) POWER SEMICONDUCTOR APPARATUS

(75) Inventors: Yoshiko Obiraki, Tokyo (JP); Seiji Oka, Tokyo (JP); Takeshi Oi, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: MITSUBISHI ELECTRIC CORPORATION, Chiyoda-ku (JP)

(21) Appl. No.: 12/540,880

(22) Filed: Aug. 13, 2009

(30) Foreign Application Priority Data
Nov. 28, 2008 (JP) 2008-304544

(51) Int. Cl. H05K 7/20; H01R 9/00

(52) U.S. Cl. 361/709; 361/822

(57) ABSTRACT

A power semiconductor apparatus has: plural power semiconductor units, sealed by a transfer mold resin so that insertion holes of conductive tubular sockets in which plural external terminals can be insertion-connected are exposed in one surface thereof and a metal heat dissipation surface is exposed in another surface thereof; and a conductive connecting member having the plural external terminals. The surfaces of the power semiconductor units that have the insertion holes of tubular sockets are arrayed in the same direction in the plural power semiconductor units. Electrical wiring connection between the plural power semiconductor units is effected by inserting the external terminals of the conductive connecting member into the respective insertion holes of the tubular sockets of the plural power semiconductor units.

### BACKGROUND OF THE INVENTION

1. Field of the Invention

This invention relates to a resin sealed type power semiconductor apparatus made by transfer molding, which is excellent in productivity, and more particularly to a power semiconductor apparatus that is small in size and achieves high current.

2. Description of the Related Art

In order to drive and control a motor using a three-phase alternating current power supply, a converting unit from alternating current to direct current, called a converter, and a converting unit from direct current to alternating current, called an inverter, are necessary. A power semiconductor apparatus is an apparatus in which these units are combined into one apparatus. Such a power semiconductor apparatus is operated at a high current and a high voltage. Therefore, it is essential for such a power semiconductor apparatus to dissipate the heat associated with its operation to the outside of the power semiconductor apparatus efficiently. For this reason, the power semiconductor apparatus is formed in the following manner. A wiring pattern is formed on a metal plate serving as a heat dissipation plate with an insulating layer interposed therebetween, a power semiconductor element is provided thereon, and the power semiconductor element is sealed by a resin.

As one example of such an apparatus, there is a power semiconductor apparatus formed of the following components (for example, see JP-A-08-316357). The power semiconductor apparatus is formed of: a metal plate serving as a heat dissipation plate; a power semiconductor element bonded on a wiring pattern formed on a ceramic plate, serving as an insulating layer, placed on the metal plate; an external lead terminal raised from the surface on which the power semiconductor element is mounted; a metal wire for connecting the external lead terminal and the power semiconductor element to each other; a thermoplastic resin outer case that is bonded to the metal plate; a silicone gel filled in a recessed portion formed by the outer case and the substrate on which the power semiconductor element is mounted; and a thermosetting resin further filled on top of the silicone gel.

However, this conventional power semiconductor apparatus necessitates a step of bonding the thermoplastic resin outer case to the metal plate, a step of filling and curing the silicone gel, and a step of impregnating and curing the thermosetting resin. Thus, the conventional power semiconductor apparatus requires many manufacturing steps and a long manufacturing time, resulting in low productivity. Moreover, this conventional power semiconductor apparatus has a low current carrying capacity per the area of the base of the module. Therefore, a problem arises that the size of the power semiconductor apparatus increases.

A power semiconductor apparatus that solves such problems and achieves a size reduction and an improvement in the productivity is a power semiconductor apparatus that has been disclosed (for example, see JP-A-11-220074). In this apparatus, the power semiconductor element is sealed with a transfer mold resin and the external terminal is taken out using a lead frame.

FIG. 6 is a perspective view showing the just-described conventional power semiconductor apparatus. In this conventional power semiconductor apparatus, the external terminals are formed by using a lead frame 25. However, with the method using the lead frame 25, the external terminals are inevitably exposed in one row from a side face of the power semiconductor apparatus because of the constraints of the manufacturing process. In a power semiconductor apparatus operated at a high current and a high voltage, the external terminals need to be disposed in such a manner that a sufficient withstand voltage between the external terminals can be ensured. However, with such a conventional method that the external terminals are exposed in one row, there is no other method than increasing the size of the power semiconductor apparatus itself in order to ensure a high withstand voltage, so the apparatus inevitably becomes larger. It should be noted that, in the figure, reference symbol 21 denotes a power semiconductor apparatus (module), reference symbols 23a and 23b denote heat spreader bodies, reference symbol 24 denotes a heat radiator, reference symbol 25 denotes a lead frame, reference symbol 26 denotes a connection wire, reference symbol 27 denotes a resin case, reference symbol 28 denotes a mounting screw hole, reference symbols 31a and 31b denote heat spreader substrates, reference symbol 32 denotes an inner lead, reference symbol 33 denotes an outer lead, reference symbol 34 denotes amounting screw hole, reference symbols D1 and D2 denote diodes, and reference symbol Tr denotes a transistor.

Furthermore, in the conventional method, the components that form the inverter and the converter are sealed with a transfer mold resin at one time. Therefore, if a defect occurs in any of the components in the apparatus, the entire apparatus needs to be replaced. This leads to the problems of a degradation of the product yield and high costs in the manufacture.

### SUMMARY OF THE INVENTION

This invention has been accomplished to solve the problems such as described above, and it is an object of the invention to provide a power semiconductor apparatus formed by sealing with a transfer mold resin that achieves an improvement in the productivity and a cost reduction and that can be used with high reliability even under high current and high voltage.

A power semiconductor apparatus according to the invention has: a plurality of power semiconductor units, sealed by a transfer mold resin so that insertion holes of conductive tubular sockets in which a plurality of external terminals can be insertion-connected are exposed in one surface thereof and a metal heat dissipation surface is exposed in another surface thereof; and a conductive connecting member having the plurality of external terminals. The surfaces of the power semiconductor units that have the insertion holes of the tubular sockets are arrayed in the same direction in the plurality of power semiconductor units. Electrical wiring connection between the plurality of power semiconductor units is effected by inserting the external terminals of the conductive connecting member into the respective insertion holes of the tubular sockets of the plurality of power semiconductor units.

According to the power semiconductor apparatus of the invention, the insertion holes of the tubular sockets in which the external terminals can be insertion-connected are exposed in one surface thereof in the power semiconductor unit sealed by a transfer mold resin, while a metal heat dissipation surface is exposed in the other surface thereof. Furthermore, electrical wiring connection between the plurality of the power semiconductor units is effected by using the conductive connecting member having a plurality of external terminals, to construct the power semiconductor apparatus. Thus, it becomes possible to increase the cross-sectional area of the surface of the tubular socket that is perpendicular to the direction in which electric current is passed, so a high current can be passed through the external terminals. Moreover, a sufficient withstand voltage between the tubular sockets can be ensured even with a small size.

The power semiconductor apparatus according to the invention uses plurality of power semiconductor units combined together. Therefore, if any of all the power semiconductor units does not meet the required quality in a quality test during manufacture, only that power semiconductor unit needs to be replaced, so the reliability can be improved at low cost in comparison with the conventional method in which the entire power semiconductor apparatus needs to be replaced.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is an exploded perspective view showing a power semiconductor apparatus before assembled, according to Embodiment 1 of the invention.

FIG. 2A is a cross-sectional view taken along line A-A of FIG. 1, showing the apparatus after assembly, and FIG. 2B is a cross-sectional view showing the apparatus in which conductive connecting members are removed therefrom and a transfer mold resin on the metal plate is also removed.

FIG. 3 is an exploded perspective view showing a power semiconductor apparatus before assembled, according to Embodiment 2.

FIG. 4A is a cross-sectional view taken along line B-B of FIG. 3, showing the apparatus after assembly, and FIG. 4B is a cross-sectional view showing the apparatus in which the conductive connecting members are removed therefrom and the transfer mold resin on the metal plate is also removed.

FIG. 5 is a cross-sectional view showing an apparatus of Embodiment 3 in which the conductive connecting members are removed therefrom and the transfer mold resin on the metal plate is also removed.

FIG. 6 is a perspective view showing a conventional power semiconductor apparatus.

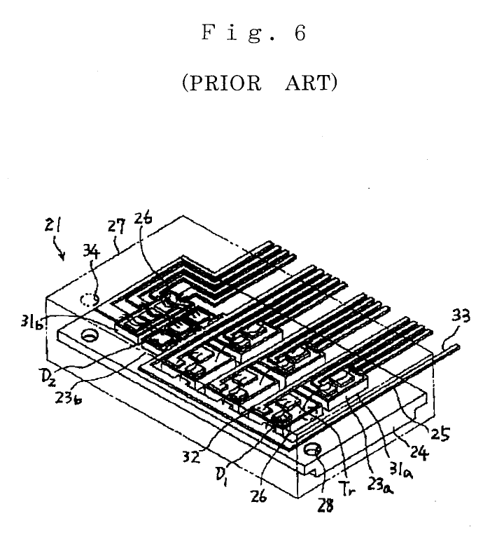

### DETAILED DESCRIPTION OF THE INVENTION

### Embodiment 1

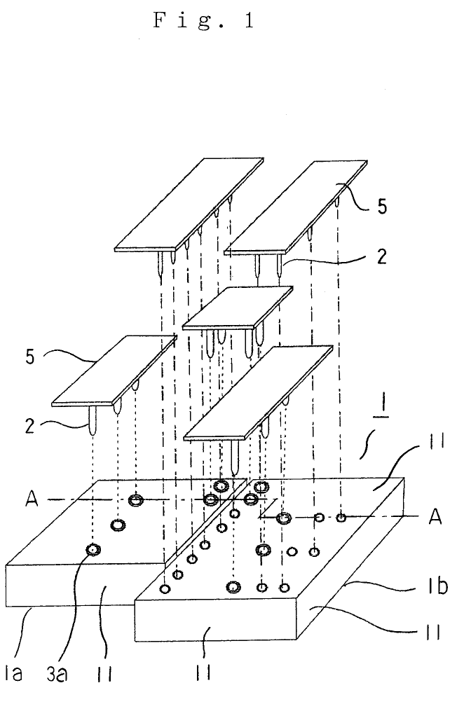

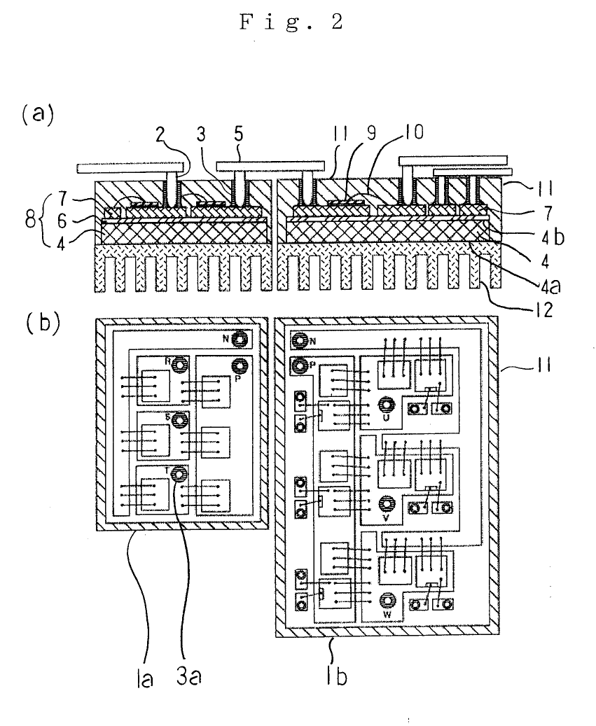

FIG. 1 is an exploded perspective view showing a power semiconductor apparatus before assembled, according to Embodiment 1 of the invention. FIG. 2A is a cross-sectional view taken along line A-A of FIG. 1, showing the apparatus after assembled, and FIG. 2B is a cross-sectional view showing the apparatus in which conductive connecting members are removed therefrom and a transfer mold resin on a metal plate 4 is also removed. As shown in FIG. 1, a power semiconductor apparatus 1 of Embodiment 1 includes a plurality of power semiconductor units 1a and 1b combined together. Each of the power semiconductor units 1a and 1b is transfer-molded so as to expose insertion holes 3a of conductive tubular sockets 3, into which external terminals 2 can be inserted and connected, in one surface thereof and to expose a heat dissipation metal surface 4a for dissipating the heat of the metal plate 4 in the other surface. The power semiconductor apparatus 1 is provided with conductive connecting members 5 each having a plurality of external terminals 2.

The surfaces of the power semiconductor units 1a and 1b that have the insertion holes 3a of the tubular sockets 3 are arrayed in the same direction in the plurality of the power semiconductor units 1a and 1b. Desirably, they are arrayed in the same direction and also in the same plane. By inserting the external terminals 2 of the conductive connecting members 5 into the respective insertion holes 3a of the tubular sockets 3 of the plurality of power semiconductor units 1a and 1b, electrical wiring connection between the plurality of power semiconductor units 1a and 1b are effected, and the plurality of power semiconductor units 1a and 1b are mechanically joined to each other so as to be united into one piece. The conductive connecting members 5 are, for example, bus bars. Although the external terminals 2 in a rod-like shape are shown as an example, they are not limited thereto, and they may be in other shapes. A printed circuit board having a plurality of layers and a laminate bus bar are preferable as the bus bar because they are effective for reducing inductance. Although Embodiment 1 employs a plurality of separate bus bars, it is not necessary to use separate bus bars, and it is possible to use a single bus bar.

In the power semiconductor apparatus 1 of Embodiment 1, the power semiconductor unit 1a constitutes a converter unit, while the power semiconductor unit 1b constitutes an inverter unit. By combining these two units, the power semiconductor apparatus 1 forms a power converter apparatus. In each the power semiconductor units 1a and 1b, a resin insulating layer 6, which is a highly heat conductive insulating layer, is provided on one surface 4b (the opposite surface to the heat dissipation metal surface 4a for dissipating heat) of the metal plate 4. A metal foil wiring pattern 7 is provided on the opposite surface to the surface of the resin insulating layer 6 that is bonded to the metal plate 4. That is, the metal plate 4, the resin insulating layer 6, and the wiring pattern 7 constitutes a metallic circuit board 8, which is a circuit board.

Power semiconductor elements 9 are bonded onto a mounting surface of the wiring pattern 7 by solder, and the tubular sockets 3 are bonded substantially perpendicularly onto the wiring pattern 7 by solder. The points between the wiring patterns 7, between the power semiconductor elements 9, and between the wiring patterns 7 and the power semiconductor elements 9 that are necessary are electrically connected to each other by wire bonds 10. The wiring pattern 7 formation surface portion and the peripheral side face portion of the metallic circuit board 8, the power semiconductor elements 9, the wire bonds 10, and the outsides of the tubular sockets 3, are sealed by a transfer mold resin 11. On the other hand, the transfer mold resin 11 is not filled in the insertion holes 3a of the tubular sockets 3.

In the plurality of power semiconductor units 1a and 1b thus configured, the surfaces thereof in which the insertion holes 3a of the tubular sockets 3 of the power semiconductor units 1a and 1b are provided are arrayed in the same direction and in the same plane. By inserting the external terminals 2 of the conductive connecting members (bus bars) 5 into the respective insertion holes 3a of the tubular sockets 3 of the plurality of power semiconductor units 1a and 1b, electrical wiring connection between the plurality of power semiconductor units 1a and 1b are effected, and the plurality of power semiconductor units 1a and 1b are mechanically joined to each other integrally. In FIG. 2B, the power semiconductor unit 1b for three phases (for U, V, and W phases) is shown, but the following configuration is also possible. Separate power semiconductor units each having independent tubular sockets for the anode side and the cathode side are provided for each one phase, and each of the power semiconductor units is transfer-molded separately. These power semiconductor units are electrically connected to each other and mechanically joined to each other, to construct a power semiconductor unit for three phases. In addition, a break circuit may be added to any of the power semiconductor units, or a power semiconductor unit that constitutes a break circuit may be prepared separately and combined with the other power semiconductor units.

The foregoing has described a power semiconductor apparatus in which electrical wiring connection between a plurality of power semiconductor units are effected and the plurality of power semiconductor units are also mechanically joined to each other by inserting the external terminals of the conductive connecting members into the respective insert holes of the tubular sockets of the plurality of power semiconductor units. However, the following configuration is also possible. Electrical wiring connection between the plurality of power semiconductor units may be effected by inserting the external terminals of the conductive connecting members into the respective insert holes of the tubular sockets of the plurality of power semiconductor units, but the mechanical joining of the plurality of power semiconductor units may be effected by placing the plurality of power semiconductor units on a common cooling fin and mechanically joining the plurality of power semiconductor units integrally. Alternatively, the plurality of power semiconductor units and a common cooling fin may be screw-fastened to mechanically join the power semiconductor units integrally.

Thus, the power semiconductor apparatus is constructed by combining power semiconductor units using the conductive connecting members 5 having a plurality of external terminals 2. Therefore, a power converter apparatus can be assembled easily. Moreover, even if any of the power semiconductor units fails or breaks, only the failed or broken power semiconductor unit needs to be replaced. Thus, reliability can be improved at low cost in comparison with the conventional method in which the entire power semiconductor apparatus needs to be replaced. Generally, it is known that, when comparing the converter unit 1a and the inverter unit 1b, the inverter unit 1b generates a greater amount of heat, while the converter unit 1a generates a less amount of heat. However, with the conventional method, it is difficult to attach cooling devices such as the cooling fin 12 at separate locations for the converter unit 1a and the inverter unit 1b. On the other hand, with the configuration of Embodiment 1, cooling devices can be mounted separately for the converter unit 1a and the inverter unit 1b. Therefore, the cooling device may be simplified for the converter unit 1a, which generates less heat. As a result, lower cost is achieved in comparison with the conventional power semiconductor apparatus.

In Embodiment 1, a metal having good thermal conductivity may be used for the metal plate 4. Examples include aluminum, an aluminum alloy, copper, a copper alloy, iron, an iron alloy, and a composite material such as copper/iron-nickel alloy/copper or aluminum/iron-nickel alloy/aluminum. In particular, it is preferable to use copper, which has excellent electrical conductivity, when a power semiconductor element 9 having high current carrying capacity is used. The thickness, length, and width of the metal plate 4 may be determined as appropriate depending on the current carrying capacity of the power semiconductor element 9. Specifically, when the current carrying capacity of the power semiconductor element 9 is greater, the thickness of the metal plate 4 is made greater and the length and width of the metal plate 4 are made greater.

In Embodiment 1, a resin insulating sheet containing various ceramics or inorganic powder, or a resin insulating sheet containing glass fibers may be used for the resin insulating layer 6. Examples of the inorganic powder that may be contained in the resin insulating layer 6 include alumina, beryllia, boron nitride, magnesia, silica, silicon nitride, and aluminum nitride. The thickness of the resin insulating layer 6 is, for example, from 20 μm to 400 μm. In Embodiment 1, a copper foil, for example, may be used for the wiring pattern 7, and aluminum wire may be used for the wire bonds 10. The thickness of the copper foil used for the wiring pattern 7, and the wire diameter and number of the aluminum wires used for the wire bonds 10 may be determined as appropriate depending on the current carrying capacity of the power semiconductor element 9.

The power semiconductor apparatus 1 is constructed by joining the metal plate 4 and the cooling fin 12 of each of the power semiconductor units. The joining is generally effected by screw-fastening, and it is preferable to use screw-fastening in Embodiment 1 as well. In Embodiment 1, a metal tube, for example, is used for each of the tubular sockets 3. The material for the metal tube should preferably be a plated product of a metal that has excellent thermal conductivity and electrical conductivity and that can be bonded with the wiring pattern 7 by solder, such as copper, a copper alloy, aluminum, and an aluminum alloy. The thickness of each of the tubular sockets 3 should preferably be a thickness that does not cause the tubular socket to be crashed by the molding pressure during the transfer molding, and it is determined as appropriate depending on the current carrying capacity.

The height of each of the tubular sockets 3 should preferably be a height such that the external terminal 2, which is to be inserted and connected thereto later, can be connected thereto sufficiently. The inner diameter of the tubular socket 3 is determined according to the outer diameter of the insertion part of the external terminal 2, which is to be inserted and connected thereto later. It should preferably be at least such an inner diameter that the external terminal 2 can be fitted thereto. In addition, the inner diameter of the tubular socket 3 at its end portion on the transfer mold resin surface side may be equal to or greater than the inner diameter of the center portion thereof. In this way, the external terminal 2 can be inserted into the tubular socket 3 easily. Furthermore, when the external terminal 2 is inserted into the tubular socket 3, the external terminal 2 comes into contact with the upper surface of the wiring pattern 7 to enable electrical connection.

In addition, in Embodiment 1, an epoxy resin in which silica powder is filled as a filler, for example, may be used for the transfer mold resin 11. The content of the silica powder filled in the transfer mold resin 11 is determined to be an optimum amount, taking the thermal expansion coefficient of the member used for the power semiconductor apparatus 1 or the like into consideration. For example, when copper is used for the wiring pattern 7 and the metal plate 4, the filling amount of the silica powder in the epoxy resin is set so that the thermal expansion coefficient of the transfer mold resin 11 is adjusted to be 16 ppm/° C., which is the thermal expansion coefficient of copper. In this way, a power semiconductor apparatus free from warpage can be obtained. In addition, when the heat dissipation capability of the transfer mold resin 11 should be improved, it is preferable to use alumina powder as the filler in place of the silica powder.

Next, one example of the manufacturing method for the power semiconductor apparatus in Embodiment 1 will be described. The power semiconductor units 1a and 1b of the power semiconductor apparatus 1 are prepared as follows. For example, a B-stage epoxy resin sheet containing alumina powder is placed on a 3 mm-thick aluminum plate, and a 0.3 mm-thick copper foil is overlapped thereon. Then, a stacked material of an aluminum plate, the epoxy resin sheet containing alumina powder, and a copper foil are heated and compressed to bond the aluminum plate and the copper foil to each other by the epoxy resin sheet containing alumina powder. Next, the wiring pattern 7 is formed by etching the copper foil. Thus, the metallic circuit board 8 having the metal plate 4 of aluminum, the resin insulating layer 6 of the epoxy resin containing alumina powder, and the wiring pattern 7 of copper is formed.

Thereafter, although not shown in FIG. 2, a solder resist, which is not essential, is formed at an arbitrary location. Next, the power semiconductor elements 9 are bonded to element mounting positions provided at desired locations on the wiring pattern 7 by solder, and also the tubular sockets 3 are bonded to bonding positions for the tubular sockets 3 provided at desired locations on the wiring pattern 7 by solder. The points that require electrical conduction between the wiring patterns 7, between the power semiconductor elements 9, and between the wiring patterns 7 and the power semiconductor elements 9 are connected to each other by aluminum wire bonds 10. Moreover, the wiring pattern 7 and the power semiconductor element 9 are connected to each other by the wire bonds 10, but this is merely illustrative, and various other ways of electrical connection may be employed.

In the foregoing manufacturing step order of soldering and then wire bonding 10, the wire bonding 10 needs to be performed after the completion of solder bonding of all the components. Therefore, there is a possibility that, when performing the wire bonding from a power semiconductor element 9 or another wiring pattern 7 onto a wiring pattern 7 that is electrically connected to the tubular sockets 3, the wire bonds may not be attached close enough due to the height of the tubular sockets 3, because of the constraints of the wire bonding equipment. As a consequence, a limitation arises in the package area. In view of this problem, the following method may be used as a method of further reducing the package area. That is a method in which the wire bonding is performed after soldering the wiring pattern 7 and the power semiconductor elements 9, and thereafter the wiring pattern 7 and the tubular sockets 3 are bonded. The bonding is performed two times separately, so either a low-melting point solder or a bonding method other than soldering is used for the bonding of the wiring pattern 7 and the tubular sockets 3. Examples include a method of bonding with silver paste and a method using ultrasonic bonding.

Next, the metallic circuit board 8 on which the power semiconductor elements 9 and the tubular sockets 3 are mounted is set in a mold and is sealed by a transfer molding method using, for example, an epoxy resin-based transfer mold resin 11 in which silica powder is filled. The insertion holes 3a of the tubular sockets 3 sealed with the transfer mold resin 11 are the portions to which the external terminals 2 are to be connected. Examples of the method of connecting the tubular sockets 3 and the external terminals 2 include soldering, compression-fitting represented by press-fitting, which is a bonding between metals, and screw-fastening. It is preferable to use compression-fitting as represented by press-fitting, which is low in cost, shows high reliability in the connected portions, and is easy to perform the process. The material for the metallic circuit board 8 is not limited to the above-described materials, and a ceramic substrate may be used as a constituent member of the power semiconductor device.

### Embodiment 2

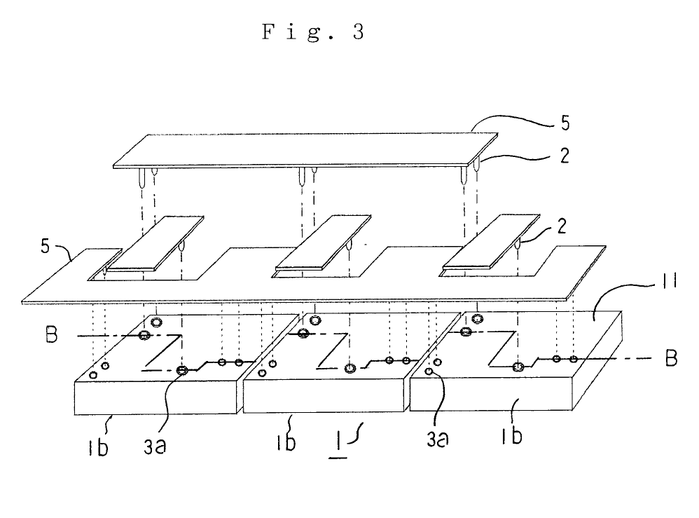

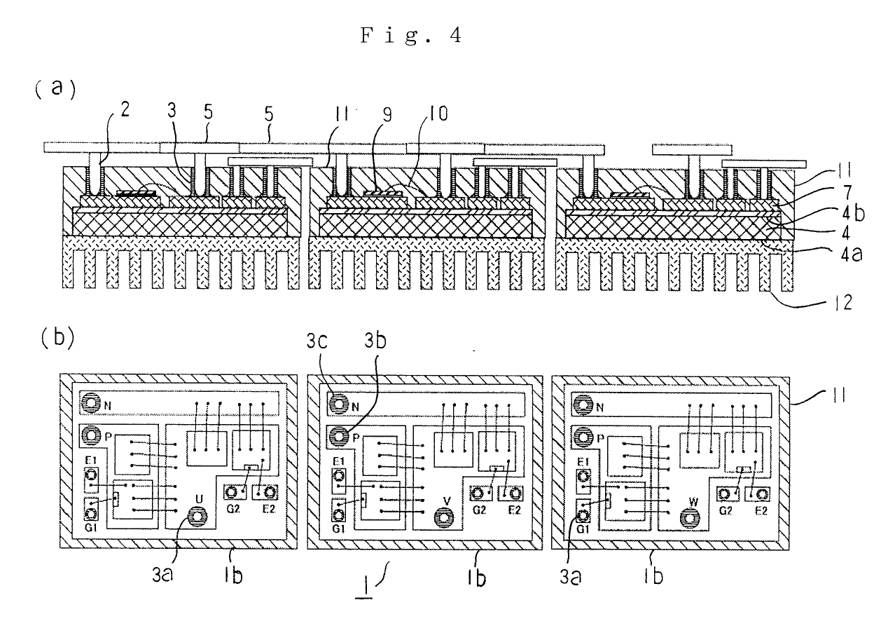

FIG. 3 is an exploded perspective view showing a power semiconductor apparatus before assembled, according to Embodiment 2. FIG. 4A is a cross-sectional view taken along line B-B of FIG. 3, showing the apparatus after assembled, and FIG. 4B is a cross-sectional view showing the apparatus in which conductive connecting members are removed therefrom and a transfer mold resin on the metal plate 4 is also removed. In the drawings, the same reference symbols refer to the same or corresponding parts. Embodiment 2 is the same as Embodiment 1 except that the chip layout is different. As shown in FIG. 4, each of three power semiconductor units 1b is an inverter unit for one phase, each containing the anode side tubular sockets 3b and the cathode side tubular sockets 3c (that is, the upper and lower arms). Each of the power semiconductor units 1b, 1b, 1b (U, V, and W phases) that are the inverter units have the same configuration, and a three-phase inverter is constructed by connecting the external terminals 2 and the conductive connecting members 5 (bus bars).

The power semiconductor apparatus is constructed using the conductive connecting members 5 having a plurality of external terminals 2. Therefore, a power converter apparatus can be assembled easily. Moreover, even if any of the power semiconductor units fails or breaks, only the failed or broken power semiconductor unit needs to be replaced. Thus, reliability can be improved at low cost in comparison with the conventional method in which the entire power semiconductor apparatus needs to be replaced.

### Embodiment 3

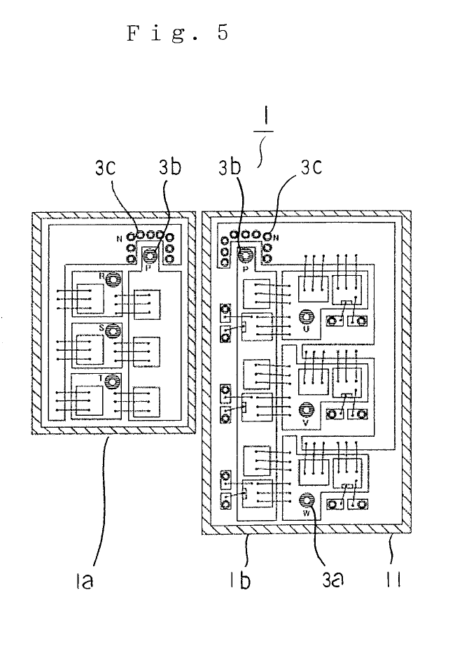

FIG. 5 is a cross-sectional view showing an apparatus of Embodiment 3 in which the conductive connecting members are removed therefrom and the transfer mold resin on the metal plate 4 is also removed. As shown in FIG. 5, a power semiconductor apparatus 1 of Embodiment 3 includes a converter unit and an inverter unit, which are power semiconductor units 1a and 1b. The power semiconductor apparatus 1 has the same configuration as that of Embodiment 1, except that anode side tubular sockets 3b and cathode side tubular sockets 3c (P·N sockets) of the power semiconductor units 1a and 1b are disposed so that the cathode side tubular sockets 3c surround the anode side tubular sockets 3b.

The cathode side tubular sockets 3c have a smaller diameter than the anode side tubular sockets 3b. The reason is that a plurality of the cathode side tubular sockets 3c exist around each of the anode side tubular sockets 3b, and therefore, the diameter of the cathode side tubular sockets can be made smaller from the viewpoint of current carrying capacity. The anode side tubular sockets 3b and the cathode side tubular sockets 3c need to be spaced apart by an insulation distance, so the wiring inductance becomes greater because of the portions of the tubular sockets 3b and 3c. However, when ones of the anode side tubular sockets 3b or the cathode side tubular sockets 3c are disposed so as to surround the other ones of the tubular sockets so that the other ones of the tubular sockets cancel the magnetic flux generated by the electric current flowing through the ones of the tubular sockets, the wiring inductance can be reduced. Accordingly, in Embodiment 3, the cathode side tubular sockets 3c are configured so as to surround the anode side tubular sockets 3b. Alternatively, it is possible that the anode side tubular sockets 3b are configured so as to surround the cathode side tubular sockets 3c. Thus, wiring inductance can be reduced.

While the presently preferred embodiments of the present invention have been shown and described. It is to be understood that these disclosures are for the purpose of illustration and that various changes and modifications may be made without departing from the scope of the invention as set forth in the appended claims.

What is claimed is:

1. A power semiconductor apparatus comprising:
a plurality of power semiconductor units, sealed by a transfer mold resin so that insertion holes of conductive tubular sockets in which a plurality of external terminals can be insertion-connected are exposed in one surface thereof and a metal heat dissipation surface is exposed in another surface thereof; and a conductive connecting member having the plurality of external terminals, the power semiconductor apparatus being configured so that:
the surfaces of the power semiconductor units that have the insertion holes of the tubular sockets are arrayed in the same direction in the plurality of power semiconductor units; and
electrical wiring connection between the plurality of power semiconductor units is effected by inserting the external terminals of the conductive connecting member into the respective insertion holes of the tubular sockets of the plurality of power semiconductor units.

2. The power semiconductor apparatus as set forth in claim 1, wherein the surfaces of the power semiconductor units having the insertion holes of the tubular sockets are directed in the same direction and arrayed in substantially the same plane in the plurality of power semiconductor units.

3. The power semiconductor apparatus as set forth in claim 1, wherein one type of the plurality of power semiconductor units is an inverter unit, and the other type thereof is a converter unit, and electrical wiring connection is effected between the two types of the power semiconductor units by the conductive connecting member.

4. The power semiconductor apparatus as set forth in claim 2, wherein one type of the plurality of power semiconductor units is an inverter unit, and the other type thereof is a converter unit, and electrical wiring connection is effected between the two types of the power semiconductor units by the conductive connecting member.

5. The power semiconductor apparatus as set forth in claim 1, further comprising:
a plurality of the power semiconductor units each being an inverter unit and having anode side tubular socket and cathode side tubular socket, wherein
electrical wiring connection is effected between the plurality of the power semiconductor units by the conductive connecting member to form a three-phase inverter structure.

6. The power semiconductor apparatus as set forth in claim 2, further comprising:
a plurality of the power semiconductor units each being an inverter unit and having anode side tubular socket and cathode side tubular socket, wherein
electrical wiring connection is effected between the plurality of the power semiconductor units by the conductive connecting member to form a three-phase inverter structure.

7. The power semiconductor apparatus as set forth in claim 1, wherein, by inserting the external terminals of the conductive connecting member into the insertion holes of the respective tubular sockets of the plurality of power semiconductor units, electrical wiring connection is effected between the plurality of power semiconductor units and also the plurality of power semiconductor units are mechanically joined to each other.

8. The power semiconductor apparatus as set forth in claim 2, wherein, by inserting the external terminals of the conductive connecting member into the insertion holes of the respective tubular sockets of the plurality of power semiconductor units, electrical wiring connection is effected between the plurality of power semiconductor units and also the plurality of power semiconductor units are mechanically joined to each other.

9. The power semiconductor apparatus as set forth in claim 1, wherein each of the power semiconductor units has anode side tubular socket and cathode side tubular socket, and the anode side tubular socket and the cathode side tubular socket are disposed so that either one of the anode side tubular socket or the cathode side tubular socket surrounds the other one, wherein the either one is comprised of a plurality of tubular sockets.

10. The power semiconductor apparatus as set forth in claim 2, wherein each of the power semiconductor units has anode side tubular socket and cathode side tubular socket, and the anode side tubular socket and the cathode side tubular socket are disposed so that either one of the anode side tubular socket or the cathode side tubular socket surrounds the other one, wherein the either one is comprised of a plurality of tubular sockets.
